(19) United States
(12) Patent Application Publication
(10) Pub. No.: US 2013/0249008 A1
(43) Pub. Date: Sep. 26, 2013

(54) SEMICONDUCTOR DEVICE

(71) Applicant: SUMITOMO ELECTRIC INDUSTRIES, LTD., Osaka-shi (JP)

(72) Inventors: Takahiro SUGIMURA, Osaka-shi (JP); Hiroshi NOTSU, Osaka-shi (JP)

(73) Assignee: Sumitomo Electric Industries, Ltd., Osaka-shi (JP)

(21) Appl. No.: 13/777,612

(22) Filed: Feb. 26, 2013

(30) Foreign Application Priority Data
Mar. 21, 2012 (JP) 2012-063276

(51) Int. Cl. H01L 23/495

(52) U.S. Cl. CPC H01L 23/495
USPC 257/368

(57) ABSTRACT

A semiconductor device includes a first semiconductor chip, a second semiconductor chip, a gate electrode terminal, and a die pad. The first semiconductor chip has a first gate electrode pad and a second gate electrode pad electrically connected to the first gate electrode pad. The second semiconductor chip has a gate electrode pad connected to the second gate electrode pad via a wiring. The gate electrode terminal is connected to the first gate electrode pad of the first semiconductor chip via a wiring. The die pad has a chip mounting surface for mounting the first and second semiconductor chips.

### CROSS-REFERENCE RELATED APPLICATIONS

This application claims priority to Provisional Application Ser. No. 61/613695, filed on Mar. 21, 2012 and claims the benefit of Japanese Patent Application No. 2012-63276, filed on Mar. 21, 2012, all of which are incorporated herein by reference in their entirety.

### BACKGROUND

1. Field

The present invention relates to a semiconductor device.

2. Related Background

Known as examples of semiconductor devices include those of a case type and those of a resin seal type (see Causes of Failures and Techniques for Improving and Evaluating Reliability of Wire Bonding Focused on Cu Wires, Technical Information Institute Co., Ltd., Jul. 29, 2011, p. 163 and p. 263). In such a semiconductor device, a semiconductor chip mounted on a die pad is connected to an electrode terminal through a wire.

### SUMMARY

On a die pad, a plurality of semiconductor chips are sometimes mounted. In a MOS-FET, a gate electrode pad of each semiconductor chip is connected to a gate electrode terminal via a wire. Therefore, a plurality of wires exist between the gate electrode pads and the gate electrode terminal. In this case, there is a possibility that the wires between the gate electrode pads and the gate electrode terminal intersect and make contact with other wires (for example, wires between source electrodes pad and a source electrode terminal).

It is an object of the present invention to provide a semiconductor device in which it is hard for the wiring between the semiconductor chips and the gate electrode terminal to make contact with another wiring.

A semiconductor device according to an aspect of the present invention includes a first semiconductor chip having a first gate electrode pad and a second gate electrode pad electrically connected to the first gate electrode pad, a second semiconductor chip having a gate electrode pad connected to the second gate electrode pad via a wiring, a gate electrode terminal connected to the first gate electrode pad of the first semiconductor chip via a wiring, and a die pad having a chip mounting surface for mounting the first and second semiconductor chips.

In this semiconductor device, the gate electrode terminal is electrically connected to the gate electrode pad of the second semiconductor chip via the wirings and the first semiconductor chip. Therefore, the wiring between the gate electrode pad of the second semiconductor chip and the gate electrode terminal is no longer required. Accordingly, a semiconductor device in which it is hard for the wiring between the first and second semiconductor chips and the gate electrode terminal to make contact with another wiring can be obtained.

In an embodiment, the material of the first and second semiconductor chips may include a wideband gap semiconductor.

With a wideband gap semiconductor, the manufacturing yield of semiconductor chips is lower than that with silicon (Si). Moreover, a wideband gap semiconductor is more expensive than silicon. Accordingly, when it is intended, similar to silicon, to manufacture a single large-sized semiconductor chip also with a wideband gap semiconductor, the manufacturing yield is lowered and the manufacturing cost is also increased. Therefore, with a wideband gap semiconductor, not a single large-sized semiconductor chip but a plurality of small-sized semiconductor chips are often mounted on a die pad.

Moreover, with a wideband gap semiconductor, a current larger than that with silicon flows in semiconductor chips. Therefore, in some cases, a plurality of wirings are connected per one semiconductor chip to disperse the current.

Consequently, with a wideband gap semiconductor, a large number of wirings are normally in most cases required between the semiconductor chips and the gate electrode terminal. However, in the above-described semiconductor device, the wiring between the gate electrode pad of the second semiconductor chip and the gate electrode terminal is no longer required.

In an embodiment, the gate electrode terminal and the die pad may be included in a lead frame.

In this case, a large number of wirings are normally in most cases required between the semiconductor chips and the gate electrode terminal. However, in the above-described semiconductor device, the wiring between the gate electrode pad of the second semiconductor chip and the gate electrode terminal is no longer required.

As mentioned above, a semiconductor device in which it is hard for the wiring between the semiconductor chips and the gate electrode terminal is hard with another wiring can be provided.

### BRIEF DESCRIPTION OF THE DRAWINGS

FIG. 1 is a plan view schematically showing a semiconductor device according to a first embodiment.

FIG. 2 is a plan view schematically showing a reference semiconductor device.

FIG. 3 is a plan view schematically showing a semiconductor device according to a second embodiment.

### DETAILED DESCRIPTION

Hereinafter, embodiments of the present invention will be described in detail with reference to the accompanying drawings. Also, in the description of the drawings, the same or corresponding components are denoted by the same reference signs, and overlapping description will be omitted.

### First Embodiment

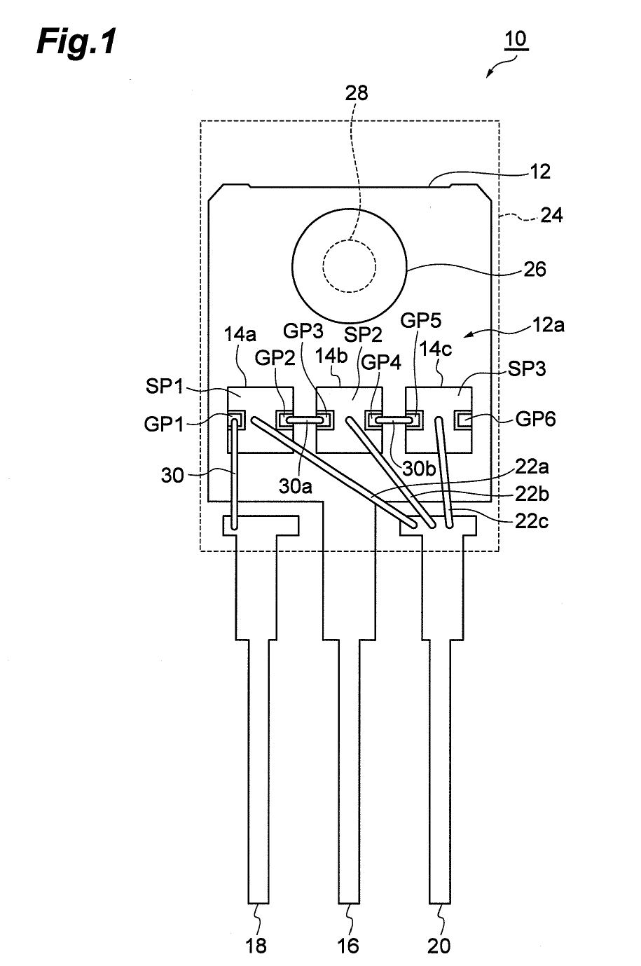

FIG. 1 is a plan view schematically showing a semiconductor device according to a first embodiment. The semiconductor device 10 shown in FIG. 1 is a resin-sealed type semiconductor device. The semiconductor device 10 includes first to third semiconductor chips 14a to 14c, a lead 18 serving as a gate electrode terminal, and a die pad 12.

The semiconductor device 10 may include leads 16 and 20 as other electrode terminals. The leads 16, 18, 20 are arrayed along a certain direction. The lead 16 is located between the leads 18, 20. The leads 16, 18, 20 and the die pad 12 can constitute a lead frame. The semiconductor device 10 is, for example, a power semiconductor device to be used for a power supply or the like. An example of the package mode of the semiconductor device 10 is a general TO series. Examples of the TO series include TO-247, TO-220, TO-263 (D2-PAK), and TO-252 (D-PAK).

The die pad 12 has a chip mounting surface 12a for mounting semiconductor chips 14a to 14c. The die pad 12 can be electrically connected with the semiconductor chips 14a to 14c. The die pad 12 shows, for example, a plate shape. The chip mounting surface 12a is, for example, rectangular. Examples of the material of the die pad 12 include metals such as copper (Cu) and copper alloy. In the die pad 12, a through-hole 26 that penetrates through the die pad 12 in the plate thickness direction can be formed. The through-hole 26 is a hole for passing therethrough a screw when, for example, fixing the semiconductor device 10 to another member by a screw.

The semiconductor chips 14a to 14c are mounted in a predetermined position of the chip mounting surface 12a. Examples of the semiconductor chips 14a to 14c include transistors such as MOS-FETs and insulated gate bipolar transistors (IGBTs). The semiconductor chips 14a to 14c can be mounted on the chip mounting surface 12a via an adhesive layer formed of a material containing a lead-based metal solder, a lead-free metal solder, or a conductive resin, etc. Examples of the material of the semiconductor chips 14a to 14c include wideband gap semiconductors and silicon and other semiconductors. A wideband gap semiconductor has a band gap larger than the band gap of silicon. Examples of the wideband gap semiconductor include silicon carbide (SiC), gallium nitride (GaN), and diamond.

The semiconductor chip 14a has a first gate electrode pad GP1 and a second gate electrode pad GP2 electrically connected to the first gate electrode pad GP1. The gate electrode pad GP1 can be electrically connected to the gate electrode pad GP2 via an internal wiring of the semiconductor chip 14a. The gate electrode pad GP1 is connected to the lead 18 via a wiring 30. The semiconductor chip 14b has a gate electrode pad GP3 that is connected to the gate electrode pad GP2 via a wiring 30a. The semiconductor chip 14b may have a gate electrode pad GP4 electrically connected to the gate electrode pad GP3. The gate electrode pad GP3 can be electrically connected to the gate electrode pad GP4 via an internal wiring of the semiconductor chip 14b. The semiconductor chip 14c has a gate electrode pad GP5 that is connected to the gate electrode pad GP4 via a wiring 30b. The semiconductor chip 14c may include a gate electrode pad GP6 so as to have the same structure as that of the semiconductor chips 14a, 14b. The gate electrode pads GP2, GP4, GP6 can be fabricated, using, for example, a photolithography method, by a similar method to that for the gate electrode pads GP1, GP3, GP5.

The gate electrode pad GP3 can be disposed opposed to the gate electrode pad GP2. In this case, it becomes hard for the wiring 30a to intersect with another wiring. The gate electrode pad GP5 can be disposed opposed to the gate electrode pad GP4. In this case, it becomes hard for the wiring 30b to intersect with another wiring.

The semiconductor chips 14a to 14c can include electrode pads SP1 to SP3, respectively. The electrode pads SP1 to SP3 are connected to the lead 20 via wirings 22a to 22c, respectively. When the semiconductor chips 14a to 14c include MOS-FETs, the electrode pads SP1 to SP3 correspond to source electrode pads. When the semiconductor chips 14a to 14c include IGBTs, the electrode pads SP1 to SP3 correspond to emitter electrode pads.

An inner end portion of the lead 16 is mechanically coupled to the die pad 12 in an integrated manner. Because the die pad 12 has conductivity, the lead 16 and the die pad 12 are electrically connected. Examples of the material of the lead 16 include the same material as the material of the die pad 12.

When the semiconductor chips 14a to 14c include MOS-FETs, the lead 16 corresponds to a drain electrode terminal, the lead 18 corresponds to a gate electrode terminal, and the lead 20 corresponds to a source electrode terminal. When the semiconductor chips 14a to 14c include IGBTs, the lead 16 corresponds to a collector electrode terminal, the lead 18 corresponds to a gate electrode terminal, and the lead 20 corresponds to an emitter electrode terminal. Examples of the material of the leads 18, 20 include metals such as copper and copper alloy. The wirings 22a to 22c, 30, 30a, 30b may be wires or ribbons. Examples of the material of the wirings 22a to 22c, 30, 30a, 30b include metals such as aluminum, gold, and copper. The wirings 22a to 22c, 30, 30a, 30b are connected to the leads 18, 20 and the semiconductor chips 14a to 14c by, for example, wire bonding using ultrasonic waves, or pressure, etc.

The die pad 12 and the semiconductor chips 14a to 14c can be sealed by a resin portion 24. The inner end portions of the leads 16, 18, 20 are fixed to the resin portion 24. Of the leads 16, 18, 20, parts that are inside of the resin portion 24 are so-called inner lead portions. Of the leads 16, 18, 20, parts that are outside of the resin portion 24 are outer lead portions. An example of the outer shape of the resin portion 24 is a substantially rectangular parallelepiped. Examples of the material of the resin portion 24 include thermoplastic resins such as polyphenylene sulfide resins (PPS resins) and liquid crystal polymers. The resin portion 24 can be formed by molding the die pad 12 and the semiconductor chips 14a to 14c with a thermoplastic resin. In the resin portion 24, a through-hole 28 using as its central axis the central axis of the through-hole 26 in the die pad 12 is formed. Similar to the through-hole 26, the through-hole 28 is a hole through which a screw is passed in the case of screw fitting or the like. The diameter of the through-hole 28 is smaller than the diameter of the through-hole 26.

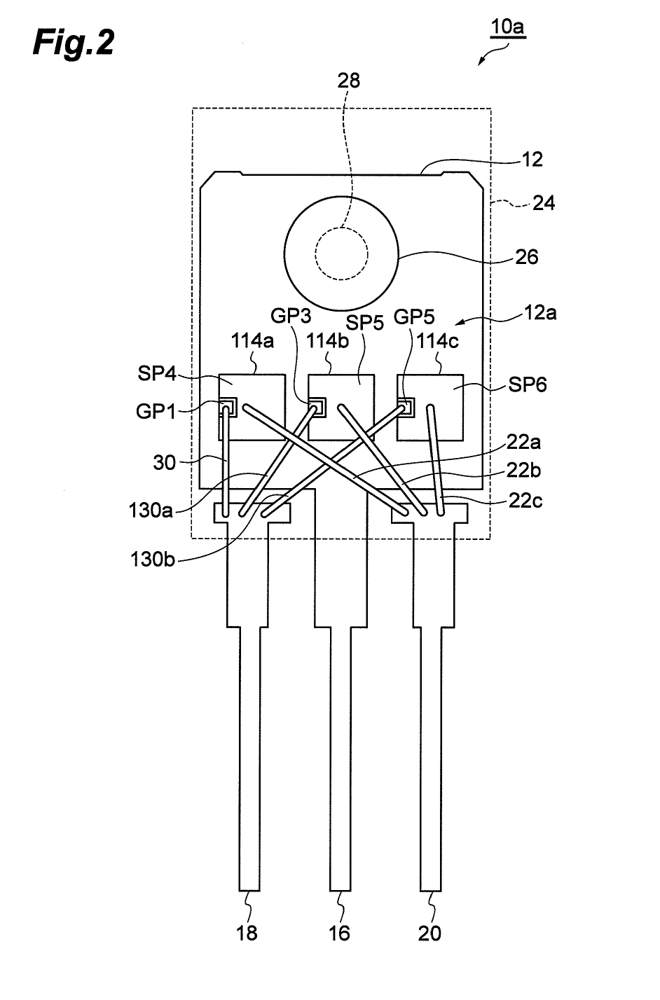

FIG. 2 is a plan view schematically showing a reference semiconductor device. The semiconductor device 10a shown in FIG. 2 includes semiconductor chips 114a to 114c in place of the semiconductor chips 14a to 14c. The semiconductor chip 114a includes no gate electrode pad GP2. The semiconductor chip 114b includes no gate electrode pad GP4. The semiconductor chip 114c includes no gate electrode pad GP6. Accordingly, the gate electrode pads GP3, GP5 are connected to the lead 18 via wirings 130a, 130b, respectively.

The semiconductor chips 114a to 114c include electrode pads SP4 to SP6, respectively. The electrode pads SP4 to SP6 are connected to the lead 20 via the wirings 22a to 22c, respectively.

In the semiconductor device 10a shown in FIG. 2, the wiring 22a intersects with the wirings 130a, 130b, and the wiring 22b intersects with the wiring 130b.

On the other hand, in the semiconductor device 10 shown in FIG. 1, the lead 18 is electrically connected to the gate electrode pad GP3 of the semiconductor chip 14b via the wirings 30, 30a and the internal wiring of the semiconductor chip 14a. Therefore, the wiring between the gate electrode pad GP3 of the semiconductor chip 14b and the lead 18 is no longer required. Similarly, the lead 18 is electrically connected to the gate electrode pad GP5 of the semiconductor chip 14c via the wirings 30, 30a, 30b and the internal wirings of the semiconductor chips 14a, 14b. Therefore, the wiring between the gate electrode pad GP5 of the semiconductor chip 14c and the lead 18 is no longer required. Between the semiconductor chips 14a to 14c and the lead 18, there is only the wiring 30. Accordingly, a semiconductor device 10 in which it is hard for the wiring 30 between the semiconductor chips 14a to 14c and the lead 18 to make contact with another wiring can be obtained.

With a wideband gap semiconductor, the manufacturing yield of semiconductor chips is lower than that with silicon. Moreover, a wideband gap semiconductor is more expensive than silicon. Accordingly, when it is intended, similar to silicon, to manufacture a single large-sized semiconductor chip also with a wideband gap semiconductor, the manufacturing yield is lowered and the manufacturing cost is also increased. Therefore, with a wideband gap semiconductor, not a single large-sized semiconductor chip but a plurality of small-sized semiconductor chips are often mounted on a die pad.

Moreover, with a wideband gap semiconductor, a current larger than that with silicon flows in semiconductor chips. Therefore, in some cases, a plurality of wirings are connected per one semiconductor chip to disperse the current.

Consequently, with a wideband gap semiconductor, a large number of wirings are normally in most cases required between the semiconductor chips and the gate electrode terminal. However, in the semiconductor device 10, the wirings to connect the semiconductor chips 14b, 14c and the lead 18 directly are no longer required.

As mentioned above, with a wideband gap semiconductor, it is particularly important to avoid intersection of the wiring 30 between the lead 18 and the semiconductor chips 14a to 14c with another wiring.

When the lead 18 and the die pad 12 are included in a lead frame, a large number of wirings are normally in most cases required between the semiconductor chips and lead. However, in the semiconductor device 10, the wirings between the semiconductor chips 14b, 14c and the lead 18 are no longer required.

### Second Embodiment

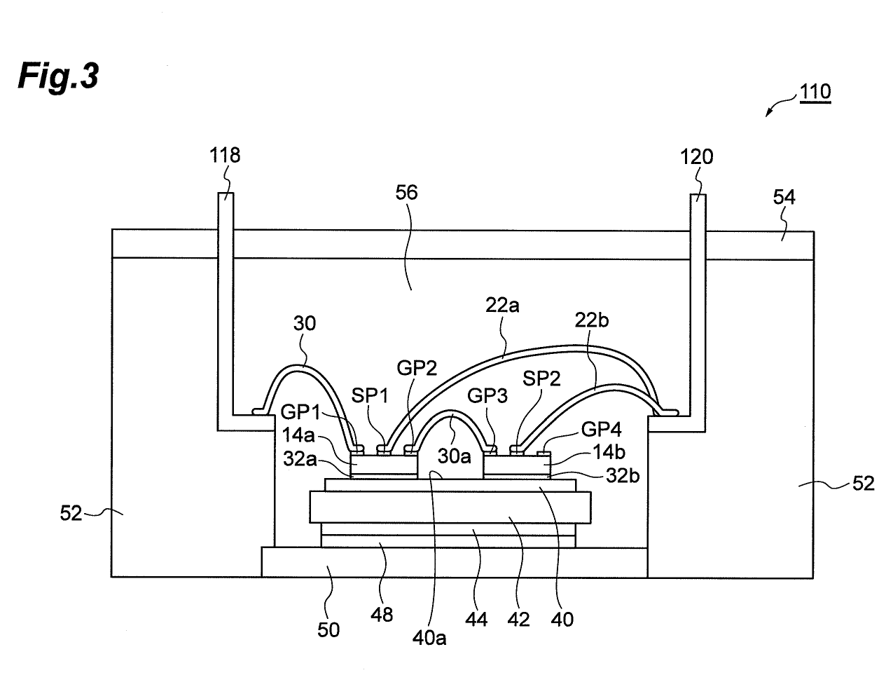

FIG. 3 is a view schematically showing a semiconductor device according to a second embodiment. The semiconductor device 110 shown in FIG. 3 is a case type semiconductor device. The semiconductor device 110 includes first and second semiconductor chips 14a, 14b, a gate electrode terminal 118, a die pad 40, and a case 52.

The die pad 40 has a chip mounting surface 40a for mounting semiconductor chips 14a, 14b. The semiconductor chips 14a, 14b are mounted on the chip mounting surface 40a via adhesive layers 32a, 32b, respectively.

The semiconductor chip 14a has a gate electrode pad GP1 and a gate electrode pad GP2 electrically connected to the gate electrode pad GP1. The semiconductor chip 14b has a gate electrode pad GP3 that is connected to the gate electrode pad GP2 via a wiring 30a. The gate electrode terminal 118 is connected to the gate electrode pad GP1 of the semiconductor chip 14a via a wiring 30.

The die pad 40 is a wiring layer provided on the front surface of an insulating substrate 42. Examples of the material of the die pad 40 include metals such as copper and copper alloy. Examples of the material of the insulating substrate 42 include ceramics such as alumina. On the back surface of the insulating substrate 42, a heat dissipation layer 44 may be provided. Examples of the material of the heat dissipation layer 44 include metals such as copper and copper alloy. The heat dissipation layer 44 is adhered to a heat sink 50 via an adhesive layer 48 made of, for example, a solder, etc. Examples of the material of the heat sink 50 include metals.

The semiconductor chips 14a, 14b, the die pad 40, the insulating substrate 42, and the heat dissipation layer 44 are housed in a case 52. The case 52 is, for example, cylindrical. One opening of the case 52 can be sealed by the heat sink 50. The other opening of the case 52 can be sealed by a lid 54. Examples of the material of the case 52 include resins such as engineering plastics including polybutylene terephthalate (PBT) and polyphenylene sulfide (PPS) resins. Examples of the material of the lid 54 include thermoplastic resins. Inside of the case 52, a gel 56 such as, for example, a silicone gel can be injected for stress relief.

The semiconductor device 110 can include an electrode terminal 120. The electrode terminal 120 is connected to electrode pads SP1, SP2 of the semiconductor chips 14a, 14b via wirings 22a, 22b, respectively. The gate electrode terminal 118 and the electrode terminal 120 are fitted to the inner wall of the case 52. The gate electrode terminal 118 and the electrode terminal 120 extend along the inner wall of the case 52, and project externally through openings formed in the lid 54. When the semiconductor chips 14a, 14b contain MOS-FETs, the electrode terminal 120 corresponds to a source electrode terminal. No drain electrode terminal is shown.

In the semiconductor device according to the second embodiment, advantageous effects similar to those of the semiconductor device 10 can at least be obtained.

As above, preferred embodiments of the present invention have been described in detail, however, the present invention is not limited to the above-described embodiments.

For example, the semiconductor device 10 includes three semiconductor chips 14a to 14c, but may not include the semiconductor chip 14c, or may include four or more semiconductor chips. Moreover, the semiconductor chips 14a to 14c may each include three or more gate electrode pads.

What is claimed is:

1. A semiconductor device comprising:
a first semiconductor chip having a first gate electrode pad and a second gate electrode pad electrically connected to the first gate electrode pad;
a second semiconductor chip having a gate electrode pad connected to the second gate electrode pad via a wiring;
a gate electrode terminal connected to the first gate electrode pad of the first semiconductor chip via a wiring; and
a die pad having a chip mounting surface for mounting the first and second semiconductor chips.

2. The semiconductor device according to claim 1, wherein a material of the first and second semiconductor chips includes a wideband gap semiconductor.

3. The semiconductor device according to claim 1, wherein the gate electrode terminal and the die pad are included in a lead frame.
